(19) United States
(12) Patent Application Publication
(10) Pub. No.: US 2025/0119114 A1
(43) Pub. Date: Apr. 10, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Sho NAGATOMO, Nagaokakyo-shi (JP)

(21) Appl. No.: 18/981,727

(22) Filed: Dec. 16, 2024

Related U.S. Application Data
(63) Continuation of application No. PCT/JP2023/028910, filed on Aug. 8, 2023.
(60) Provisional application No. 63/396,270, filed on Aug. 9, 2022.

(51) Int. Cl. H03H 9/13; H03H 9/02; H03H 9/17

(52) U.S. Cl. CPC H03H 9/132; H03H 9/02031; H03H 9/02157; H03H 9/02228; H03H 9/173; H03H 9/175; H03H 9/176

(57) ABSTRACT

An acoustic wave device includes a piezoelectric layer, a first comb-shaped electrode on the piezoelectric layer, including a first busbar and first electrode fingers, and connected to an input potential, a second comb-shaped electrode on the piezoelectric layer, including a second busbar and second electrode fingers interdigitated with the first electrode fingers, and connected to an output potential, and a reference potential electrode connected to a reference potential and including third electrode fingers on the piezoelectric layer aligned with the first and second electrode fingers, and a connection electrode connecting adjacent third electrode fingers. An order in which a first electrode finger, a second electrode finger, and a third electrode finger are arranged is such that, starting from the first electrode finger, the first electrode finger, the third electrode finger, the second electrode finger, and the third electrode finger define one period.

### CROSS REFERENCE TO RELATED APPLICATIONS

This application claims the benefit of priority to Provisional Application No. 63/396,270 filed on Aug. 9, 2022 and is a Continuation of Application PCT Application No. PCT/JP2023/028910 filed on Aug. 8, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in filters for mobile phones and the like. An acoustic wave device using bulk waves in a thickness-shear mode has recently been proposed, as described in U.S. Pat. No. 10,491,192. In this acoustic wave device, a piezoelectric layer is provided on a support. A pair of electrodes are provided on the piezoelectric layer. The pair of electrodes face each other on the piezoelectric layer and are connected to different potentials. An AC voltage is applied between the electrodes to excite bulk waves in the thickness-shear mode.

An acoustic wave device is, for example, an acoustic wave resonator, and is used in a ladder filter, for example. In order to obtain good characteristics in the ladder filter, the electrostatic capacitance ratio needs to be increased between a plurality of acoustic wave resonators. In this case, the electrostatic capacitances of some of the acoustic wave resonators in the ladder filter need to be increased.

In order to increase the electrostatic capacitance of the acoustic wave resonator, for example, the acoustic wave resonator needs to be increased in size. For this reason, in the case of using such an acoustic wave resonator in a ladder filter, the ladder filter tends to be increased in size. In particular, a ladder filter having an acoustic wave resonator that uses a thickness-shear mode bulk wave with a small electrostatic capacitance tends to be increased in size.

The inventors of example embodiments of the present invention have discovered that when an acoustic wave device is used in a filter device, providing the following configuration of the acoustic wave device can obtain a suitable filter waveform without increasing the size. In this configuration, an electrode connected to a reference potential is disposed between an electrode connected to an input potential and an electrode connected to an output potential.

The inventors of example embodiments of the present invention have also discovered that simply providing the above configuration may result in degradation of the filter characteristics.

### SUMMARY OF THE INVENTION

Example embodiments of the present invention provide acoustic wave devices each achieving miniaturization of a filter device and reducing or preventing degradation of the filter characteristics.

An acoustic wave device according to an example embodiment of the present invention includes a piezoelectric layer made of lithium niobate, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer and being aligned with the first electrode fingers and the second electrode fingers in a direction in which the first electrode fingers and the second electrode fingers are arranged, and a connection electrode connecting adjacent third electrode fingers, an order in which a first electrode finger, a second electrode finger, and a third electrode finger are arranged is such that, starting from the first electrode finger, the first electrode finger, the third electrode finger, the second electrode finger, and the third electrode finger define one period, and a center-to-center distance between the first electrode finger and the second electrode finger adjacent to each other is constant in the first comb-shaped electrode and the second comb-shaped electrode, the plurality of third electrode fingers are equally or substantially equally spaced apart in the reference potential electrode, and a center-to-center distance between the first electrode finger and the third electrode finger adjacent to each other and a center-to-center distance between the second electrode finger and the third electrode finger adjacent to each other are not constant.

An acoustic wave device according to an example embodiment of the present invention includes a piezoelectric layer made of lithium niobate, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, a reference potential electrode connected to a reference potential and including a plurality of third electrode fingers on the piezoelectric layer and being aligned with the first electrode fingers and the second electrode fingers in a direction in which the first electrode fingers and the second electrode fingers are arranged, and a connection electrode connecting adjacent third electrode fingers, and at least one fourth electrode finger on the piezoelectric layer and adjacent to a first electrode finger, a second electrode finger or a third electrode finger, in a region where the fourth electrode finger is not provided, an order in which the first electrode finger, the second electrode finger, and the third electrode finger are arranged is such that, starting from the first electrode finger, the first electrode finger, the third electrode finger, the second electrode finger, and the third electrode finger define one period, and the fourth electrode finger is not connected to the input potential, the output potential, or the reference potential.

An acoustic wave device according to an example embodiment of the present invention includes a piezoelectric layer made of lithium niobate, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer so and being aligned with the first electrode fingers and the second electrode fingers in a direction in which the first electrode fingers and the second electrode fingers are arranged, and a connection electrode connecting adjacent third electrode fingers, an order in which a first electrode finger, a second electrode finger, and a third electrode finger are arranged is such that, starting from the first electrode finger, the first electrode finger, the third electrode finger, the second electrode finger, and the third electrode finger define one period, and w1≠w2, where w1 is a width of the first electrode finger and w2 is a width of the second electrode finger.

An acoustic wave device according to an example embodiment of the present invention includes a piezoelectric layer made of lithium niobate, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer so as to be aligned with the first electrode fingers and the second electrode fingers in a direction in which the first electrode fingers and the second electrode fingers are arranged, and a connection electrode connecting adjacent third electrode fingers, an order in which a first electrode finger, a second electrode finger, and a third electrode finger are arranged is such that, starting from the first electrode finger, the first electrode finger, the third electrode finger, the second electrode finger, and the third electrode finger define one period, and a center-to-center distance between the adjacent first electrode fingers and a center-to-center distance between the adjacent second electrode fingers are constant in the first comb-shaped electrode and the second comb-shaped electrode, a center-to-center distance between the adjacent third electrode fingers is not constant in the reference potential electrode, and a center-to-center distance between the first electrode finger and the third electrode finger adjacent to each other is different from a center-to-center distance between the second electrode finger and the third electrode finger adjacent to each other.

Example embodiments of the present invention provide acoustic wave devices each achieving miniaturization of a filter device and reducing or preventing degradation of filter characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view illustrating the vicinity of first to third electrode fingers in the first example embodiment of the present invention.

FIG. 4 is a schematic plan view of an acoustic wave device according to a reference example.

FIG. 5 is a graph illustrating bandpass characteristics of the acoustic wave device according to the reference example.

FIG. 6 is a graph illustrating bandpass characteristics of the acoustic wave device according to the first example embodiment of the present invention.

FIG. 7 is a diagram illustrating a map of a fractional band width with respect to Euler angles (0°, θ, ψ) of LiNbO₃ when d/p is infinitely close to 0.

FIG. 8 is a schematic plan view of an acoustic wave device according to a modification of the first example embodiment of the present invention.

FIG. 9 is a schematic plan view of an acoustic wave device according to a second example embodiment of the present invention.

FIG. 10 is a graph illustrating bandpass characteristics of the acoustic wave devices according to the second example embodiment of the present invention and the reference example.

FIG. 11 is a schematic plan view of an acoustic wave device according to a first modification of the second example embodiment of the present invention.

FIG. 12 is a schematic plan view of an acoustic wave device according to a second modification of the second example embodiment of the present invention.

FIG. 13 is a schematic plan view of an acoustic wave device according to a third example embodiment of the present invention.

FIG. 14 is a graph illustrating bandpass characteristics of the acoustic wave devices according to the third example embodiment of the present invention and the reference example.

FIG. 15 is a schematic plan view of an acoustic wave device according to a fourth example embodiment of the present invention.

FIG. 16 is a graph illustrating bandpass characteristics of the acoustic wave devices according to the fourth example embodiment where p1<p2 and the reference example where p1=p2.

FIG. 17 is a graph illustrating bandpass characteristics of the acoustic wave devices according to the fourth example embodiment where p1>p2 and the reference example where p1=p2.

FIG. 18A is a schematic perspective view illustrating an appearance of an acoustic wave device that uses a thickness-shear mode bulk wave, and FIG. 18B is a plan view illustrating an electrode structure on a piezoelectric layer.

FIG. 19 is a cross-sectional view of a portion taken along line A-A in FIG. 18A.

FIG. 20A is a schematic elevational cross-sectional view for explaining a Lamb wave propagating through a piezoelectric film of the acoustic wave device, and FIG. 20B is a schematic elevational cross-sectional view for explaining a bulk wave in the thickness-shear mode propagating through the piezoelectric film of the acoustic wave device.

FIG. 21 is a diagram illustrating an amplitude direction of the thickness-shear mode bulk wave.

FIG. 22 is a graph illustrating resonance characteristics of the acoustic wave device using the thickness-shear mode bulk wave.

FIG. 23 is a graph illustrating a relationship between d/p and a fractional band width of a resonator, where p is the center-to-center distance between adjacent electrodes and d is the thickness of the piezoelectric layer.

FIG. 24 is a plan view of the acoustic wave device using the thickness-shear mode bulk wave.

FIG. 25 is a diagram illustrating resonance characteristics of an acoustic wave device in a reference example where a spurious response appears.

FIG. 26 is a diagram illustrating a relationship between a fractional band width and a phase rotation amount of a spurious impedance normalized by about 180 degrees as a magnitude of spurious.

FIG. 27 is a diagram illustrating a relationship between d/2p and a metallization ratio MR.

FIG. 28 is a diagram illustrating a map of the fractional band width with respect to Euler angles (0°, θ, ψ) of LiNbO₃ when d/p is infinitely close to 0.

FIG. 29 is an elevational cross-sectional view of an acoustic wave device including an acoustic multilayer film.

FIG. 30 is a partially cutaway perspective view for explaining an acoustic wave device that uses a Lamb wave.

### DETAILED DESCRIPTION OF THE EXAMPLE EMBODIMENTS

The present invention will be clarified below by describing specific example embodiments of the present invention with reference to the drawings.

The example embodiments described in this specification are illustrative, and partial substitution or combination of configurations is possible between different example embodiments.

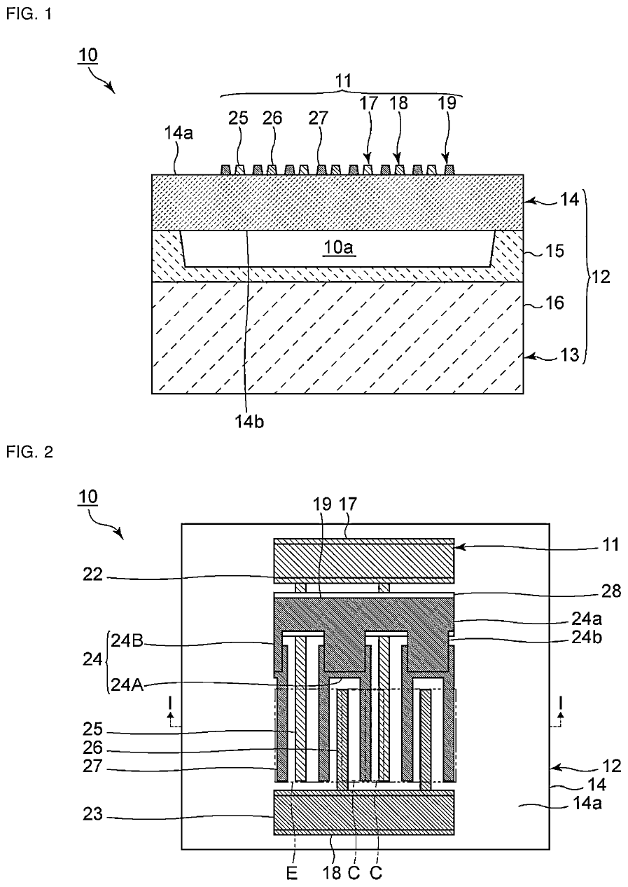

FIG. 1 is a schematic elevational cross-sectional view of an acoustic wave device according to a first example embodiment of the present invention. FIG. 2 is a schematic plan view of the acoustic wave device according to the first example embodiment. Note that FIG. 1 is a schematic cross-sectional view taken along line I-I in FIG. 2. In FIG. 2, each electrode is illustrated with hatching. Electrodes may also be hatched in schematic plan views other than FIG. 2.

An acoustic wave device 10 illustrated in FIG. 1 is configured to be able to use a thickness-shear mode. The acoustic wave device 10 is an acoustically coupled filter. The configuration of the acoustic wave device 10 will be described below.

The acoustic wave device 10 includes a piezoelectric substrate 12 and a functional electrode 11. The piezoelectric substrate 12 has piezoelectricity. Specifically, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may include the support substrate 16 only. The support 13 does not necessarily have to be provided.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

The piezoelectric layer 14 is made of lithium niobate, for example. More specifically, in the present example embodiment, the lithium niobate used for the piezoelectric layer 14 is, for example, LiNbO₃. Euler angles (φ, θ, ψ) of this LiNbO₃ are (0°, 0°, 90°). However, the Euler angles (φ, θ, ψ) of the piezoelectric layer 14 are not limited to the above. In this specification, a certain member being made of a certain material includes a case where a trace amount of impurities is included to the extent that the electrical characteristics of the acoustic wave device are not significantly deteriorated.

A functional electrode 11 is provided on the first main surface 14a of the piezoelectric layer 14. As illustrated in FIG. 2, the functional electrode 11 includes a pair of comb-shaped electrodes and a reference potential electrode 19. The reference potential electrode 19 is connected to a reference potential. The pair of comb-shaped electrodes are specifically a first comb-shaped electrode 17 and a second comb-shaped electrode 18. The first comb-shaped electrode 17 is connected to an input potential. The second comb-shaped electrode 18 is connected to an output potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. The plurality of first electrode fingers 25 each include one end connected to the first busbar 22. The second comb-shaped electrode 18 includes a second busbar 23 and a plurality of second electrode fingers 26. The plurality of second electrode fingers 26 each include one end connected to the second busbar 23.

The first busbar 22 and the second busbar 23 face each other. The plurality of first electrode fingers 25 and the plurality of second electrode fingers 26 are interdigitated with each other. The first electrode fingers 25 and the second electrode fingers 26 are alternately arranged in a direction orthogonal or substantially orthogonal to a direction in which the first electrode fingers 25 and the second electrode fingers 26 extend.

The reference potential electrode 19 includes a third busbar 24 as a connection electrode and a plurality of third electrode fingers 27. The plurality of third electrode fingers 27 are provided on the first main surface 14a of the piezoelectric layer 14. The plurality of third electrode fingers 27 extend parallel or substantially parallel to the plurality of first electrode fingers 25 and the plurality of second electrode fingers. Hereinafter, the direction in which the first electrode fingers 25, the second electrode fingers 26, and the third electrode fingers 27 extend will be referred to as an electrode finger extending direction, and the direction orthogonal or substantially orthogonal to the electrode finger extending direction will be referred to as an electrode finger orthogonal direction. In this specification, the first electrode fingers 25, the second electrode fingers 26, and the third electrode fingers 27 may be collectively referred to simply as electrode fingers.

The third electrode fingers 27 are provided so as to be aligned with the first electrode fingers 25 and the second electrode fingers 26 in the direction in which the first electrode fingers 25 and the second electrode fingers 26 are arranged. Thus, the first electrode fingers 25, the second electrode fingers 26, and the third electrode fingers 27 are arranged in one direction. When the direction in which the first electrode fingers 25, the second electrode fingers 26, and the third electrode fingers 27 are arranged is referred to as an electrode finger arrangement direction, the electrode finger arrangement direction is parallel or substantially parallel to the electrode finger orthogonal direction. Two of the third electrode fingers 27 are located at both end portions in the electrode finger orthogonal direction in the region where the plurality of electrode fingers are provided. The plurality of third electrode fingers 27 other than the two third electrode fingers 27 are provided between the first electrode fingers 25 and the second electrode fingers 26.

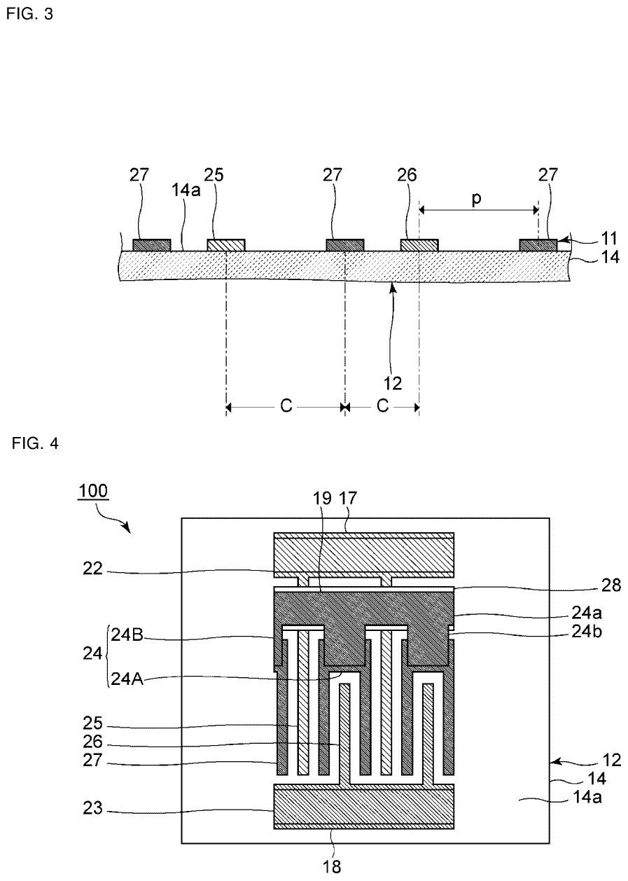

FIG. 3 is a schematic elevational cross-sectional view illustrating the vicinity of the first to third electrode fingers in the first example embodiment.

The plurality of electrode fingers are arranged as follows. Specifically, starting from the first electrode finger 25, one period includes the first electrode finger 25, the third electrode finger 27, the second electrode finger 26, and the third electrode finger 27. Therefore, the order in which the plurality of electrode fingers are arranged is the first electrode finger 25, the third electrode finger 27, the second electrode finger 26, the third electrode finger 27, the first electrode finger 25, the third electrode finger 27, the second electrode finger 26, . . . and so on. The order of the plurality of electrode fingers is represented as the order of the potentials to be connected, IN, GND, OUT, GND, IN, GND, OUT, . . . and so on, where IN represents the input potential, OUT represents the output potential, and GND represents the reference potential.

In the present example embodiment, in the region where the plurality of electrode fingers are provided, the electrode fingers located at both end portions in the electrode finger orthogonal direction are the third electrode fingers 27. The electrode fingers located at the end portions in the electrode finger orthogonal direction may be any kind of the first electrode fingers 25, the second electrode fingers 26, and the third electrode fingers 27.

As illustrated in FIG. 3, the center-to-center distance between adjacent electrode fingers is not constant. As illustrated in FIG. 2, the center-to-center distance between the adjacent first electrode finger 25 and second electrode finger 26 is constant in the first comb-shaped electrode 17 and the second comb-shaped electrode 18. In the reference potential electrode 19, the third electrode fingers 27 are arranged equally or substantially equally spaced apart. In this specification, the electrode fingers being arranged equally or substantially equally spaced apart is synonymous with the electrode fingers being arranged so that the center-to-center distance between the electrode fingers is constant. On the other hand, the first electrode finger 25 and the second electrode finger 26 are each located at a position shifted from the center of a region between the adjacent third electrode fingers 27 in the reference potential electrode 19.

Each electrode finger of the functional electrode 11 includes a multilayer metal film. Specifically, for example, in each electrode finger, a Ti layer, an AlCu layer, and a Ti layer are laminated in this order from the piezoelectric layer 14 side. The material of each electrode finger is not limited to the above. Alternatively, each electrode finger may include a single layer of metal film.

As illustrated in FIG. 2, the third busbar 24 as the connection electrode for the reference potential electrode 19 electrically connects the plurality of third electrode fingers to each other. Specifically, the third busbar 24 is located in a region between the first busbar 22 and leading end portions of the plurality of second electrode fingers 26. The plurality of first electrode fingers 25 are also located in this region. The third busbar 24 and the plurality of first electrode fingers 25 are electrically insulated from each other by the insulating film 28.

More specifically, the third busbar 24 includes a plurality of first connection electrodes 24A and one second connection electrode 24B. Each of the first connection electrodes 24A connects leading end portions of two adjacent third electrode fingers 27. The first connection electrode 24A and the two third electrode fingers 27 define a U-shaped electrode. The second connection electrode 24B connects the plurality of first connection electrodes 24A to each other. The insulating film 28 is provided between this second connection electrode 24B and the plurality of first electrode fingers 25.

To be more specific, the insulating film 28 is provided on the first main surface 14a of the piezoelectric layer 14 so as to partially cover the plurality of first electrode fingers 25. The insulating film 28 is provided in the region between the first busbar 22 and the leading end portions of the plurality of second electrode fingers 26. The insulating film 28 has a strip shape.

The insulating film 28 does not extend to the first connection electrode 24A of the reference potential electrode 19. The second connection electrode 24B is provided on the insulating film 28 and over the plurality of first connection electrodes 24A. Specifically, the second connection electrode 24B includes a bar portion 24a and a plurality of protrusions 24b. Each protrusion 24b extends from the bar portion 24a toward a corresponding one of the first connection electrodes 24A. Each protrusion 24b is connected to a corresponding one of the first connection electrodes 24A. The third electrode fingers 27 are thus electrically connected to each other by the first connection electrode 24A and the second connection electrode 24B.

In the present example embodiment, the third busbar 24 is located in the region between the first busbar 22 and the leading end portions of the plurality of second electrode fingers 26. Therefore, the leading end portions of the plurality of second electrode fingers 26 face the third busbar 24 with a gap therebetween in the electrode finger extending direction. On the other hand, the leading end portions of the plurality of first electrode fingers 25 face the second busbar 23 with a gap therebetween in the electrode finger extending direction.

The third busbar 24 may be located in a region between the second busbar 23 and the leading end portions of the plurality of first electrode fingers 25. In this case, the leading end portions of the plurality of first electrode fingers 25 each face the third busbar 24 with a gap therebetween. On the other hand, the leading end portions of the plurality of second electrode fingers 26 face the first busbar 22 with a gap therebetween.

The acoustic wave device 10 is an acoustic wave resonator configured to be able to excite a thickness-shear mode bulk wave. As illustrated in FIG. 2, the acoustic wave device 10 includes a plurality of excitation regions C. In the plurality of excitation regions C, the thickness-shear mode bulk waves and acoustic waves in other modes are excited. FIG. 2 illustrates only two of the plurality of excitation regions C.

Some of the plurality of excitation regions C are regions where the adjacent first electrode finger 25 and third electrode finger 27 overlap when viewed from the electrode finger orthogonal direction, and also regions between the centers of the adjacent first electrode finger 25 and third electrode finger 27. The rest of the excitation regions C are regions where the adjacent second electrode finger 26 and third electrode finger 27 overlap when viewed from the electrode finger orthogonal direction, and also regions between the centers of the adjacent second electrode finger 26 and third electrode finger 27. These excitation regions C are arranged in the electrode finger orthogonal direction.

The configuration of the functional electrode 11, except for the reference potential electrode 19, is the same or substantially the same as that of an interdigital transducer (IDT) electrode. When viewed from the electrode finger orthogonal direction, the region where the adjacent first electrode finger 25 and second electrode finger 26 overlap is an intersection region E. The intersection region E includes a plurality of excitation regions C. The intersection region E and the excitation region C are regions of the piezoelectric layer 14 defined based on the configuration of the functional electrode 11.

The present example embodiment is characterized by having the following configuration. 1) In the first comb-shaped electrode 17 and the second comb-shaped electrode 18, the center-to-center distance between the adjacent first electrode finger 25 and second electrode finger 26 is constant. 2) The plurality of third electrode fingers 27 are arranged equally or substantially equally spaced apart in the reference potential electrode 19. 3) The center-to-center distance between the adjacent first electrode finger 25 and third electrode finger 27 and the center-to-center distance between the adjacent second electrode finger 26 and third electrode finger 27 are not constant. This makes it possible to achieve miniaturization of a filter device and reduce or prevent degradation of the filter characteristics when the acoustic wave device 10 is used in the filter device. This will be described below by comparing the present example embodiment with a reference example.

As illustrated in FIG. 4, the reference example differs from the first example embodiment in that the first electrode fingers 25, the second electrode fingers 26, and the third electrode fingers 27 are arranged equally or substantially equally spaced apart. An acoustic wave device 100 of the reference example is also an acoustically coupled filter, as with the acoustic wave device 10 of the first example embodiment. The configurations of the first comb-shaped electrode 17, the second comb-shaped electrode 18, and the reference potential electrode 19 of the reference example are the same or substantially the same as those of the first example embodiment. However, as described above, the reference example differs from the first example embodiment in the positional relationship between the plurality of electrode fingers.

The bandpass characteristics are compared between the first example embodiment and the reference example. The design parameters of the acoustic wave device 10 having the configuration of the first example embodiment are as follows. The design parameters in the reference example are the same or substantially the same as those in the first example embodiment, except for the center-to-center distance between adjacent electrode fingers.

### Piezoelectric Layer

Material: LiNbO₃
Euler angles (φ, θ, ψ): (0°, 0°, 90°)
Thickness: about 400 nm

### First to Third Electrode Fingers

Layer structure: Ti layer/AlCu layer/Ti layer from the piezoelectric layer side
Thickness of each layer: about 10 nm/about 390 nm/about 4 nm from the piezoelectric layer side
Order of the first to third electrode fingers expressed by the potential to be connected: IN, GND, OUT, and GND are repeated in this order.
Center-to-center distance between first electrode finger and second electrode finger: about 2.8 μm
Duty ratio of functional electrode: about 0.3

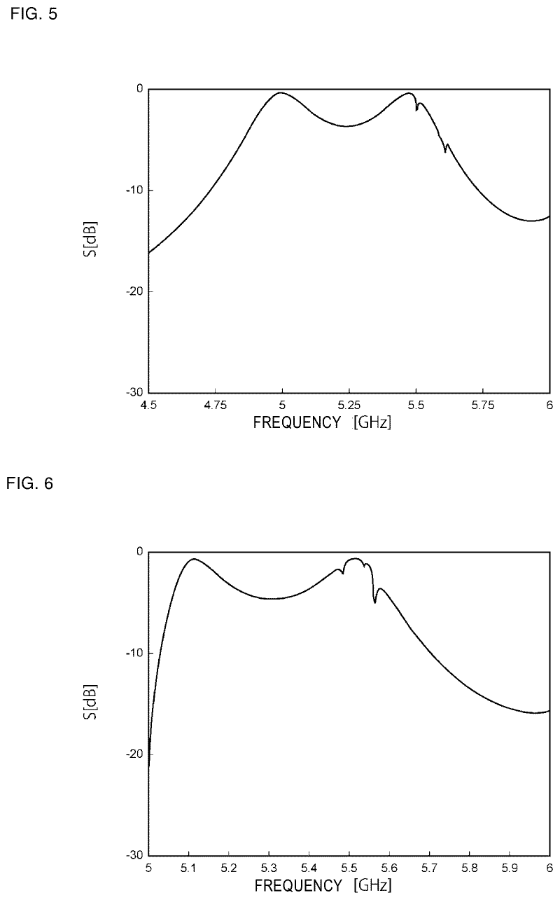

FIG. 5 is a graph illustrating bandpass characteristics of the acoustic wave device according to the reference example. FIG. 6 is a graph illustrating bandpass characteristics of the acoustic wave device according to the first example embodiment. Note that S parameters represent the bandpass characteristics.

As can be seen from FIGS. 5 and 6, a filter waveform can be suitably obtained even with a single acoustic wave device. This is because the acoustic wave devices of the first example embodiment and the reference example are acoustically coupled filters.

More specifically, as illustrated in FIG. 2, the acoustic wave device 10 of the first example embodiment includes an excitation region C located between the centers of the adjacent first electrode finger 25 and third electrode finger 27, and an excitation region C located between the centers of the adjacent second electrode finger 26 and third electrode finger 27. In these excitation regions C, acoustic waves in a plurality of modes including a thickness-shear mode bulk wave are excited. By coupling these modes, a filter waveform can be suitably obtained even with a single acoustic wave device 10.

When the acoustic wave device 10 is used as an acoustic wave resonator in a filter device, a filter waveform can be suitably obtained even with one or a small number of acoustic wave resonators that constitute the filter device. This makes it possible to achieve the miniaturization of the filter device.

However, in the reference example illustrated in FIG. 5, the steepness is low on the low-frequency side and the high-frequency side of the pass band. In the first example embodiment illustrated in FIG. 6, on the other hand, the steepness is high on the low-frequency side of the pass band. In this specification, high steepness means that the change in frequency is small for a certain amount of attenuation or change in S parameters near the end portion of the pass band.

As illustrated in FIG. 2, in the first example embodiment, the center-to-center distance between the adjacent first electrode finger 25 and third electrode finger 27 and the center-to-center distance between the adjacent second electrode finger 26 and third electrode finger 27 are not constant. This allows the frequency of the mode to be changed. This makes it possible to provide an attenuation pole on the low-frequency side. Therefore, the steepness can be increased on the low-frequency side of the pass band. The filter characteristics can thus be improved.

On the other hand, in the first comb-shaped electrode 17 and the second comb-shaped electrode 18, the center-to-center distance between the adjacent first electrode finger 25 and second electrode finger 26 is constant. In the reference potential electrode 19, the plurality of third electrode fingers 27 are arranged to be equally or substantially equally spaced apart. This makes it possible to more reliably reduce or prevent the degradation of the filter characteristics.

The configuration of the first example embodiment will be described in more detail below.

As illustrated in FIG. 1, the support 13 includes the support substrate 16 and the insulating layer 15. The piezoelectric substrate 12 is a multilayer body including the support substrate 16, the insulating layer 15, and the piezoelectric layer 14. Specifically, the piezoelectric layer 14 and the support 13 overlap when viewed from the direction in which the first main surface 14a and the second main surface 14b of the piezoelectric layer 14 face each other.

Examples of the material of the support substrate 16 include a semiconductor such as silicon, ceramics such as aluminum oxide, and the like. The insulating layer 15 can be made of an appropriate dielectric such as, for example, silicon oxide or tantalum oxide. The piezoelectric layer 14 may be, for example, a lithium niobate layer such as a LiNbO₃ layer.

The insulating layer 15 includes a recess portion. The piezoelectric layer 14 is provided on the insulating layer 15 so as to close the recess portion. A hollow portion is thus provided. This hollow portion is a cavity 10a. In the first example embodiment, the support 13 and the piezoelectric layer 14 are disposed so that a portion of the support 13 and a portion of the piezoelectric layer 14 face each other across the cavity 10a. However, the recess portion in the support 13 may be provided across the insulating layer 15 and the support substrate 16. Alternatively, a recess portion provided only in the support substrate 16 may be closed by the insulating layer 15. The recess portion may be provided in the piezoelectric layer 14. The cavity 10a may be a through-hole provided in the support 13.

The cavity 10a is an acoustic reflection portion. The acoustic reflection portion can effectively confine the energy of the acoustic wave to the piezoelectric layer 14 side. The acoustic reflection portion may be provided at a position on the support 13 that overlaps at least a portion of the functional electrode 11 in plan view. More specifically, the first electrode finger 25, the second electrode finger 26, and the third electrode finger 27 may each at least partially overlap with the acoustic reflection portion in plan view. In plan view, a plurality of excitation regions C preferably overlap with the acoustic reflection portion.

In this specification, a plan view refers to a view along the lamination direction of the support 13 and the piezoelectric layer 14 from a direction corresponding to the upper side in FIG. 1. In FIG. 1, for example, of the support substrate 16 side and the piezoelectric layer 14 side, the piezoelectric layer 14 side is the upper side. Furthermore, in this specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a normal or substantially normal direction of the first main surface 14a.

The acoustic reflection portion may be an acoustic reflection film such as, for example. an acoustic multilayer film, which will be described later. For example, the acoustic reflection film may be provided on the surface of the support.

In the first example embodiment, the center-to-center distance between the adjacent first electrode finger 25 and third electrode finger 27 and the center-to-center distance between the adjacent second electrode finger 26 and third electrode finger 27 are not constant. Hereinafter, p is the longest distance of the center-to-center distance between the adjacent first electrode finger 25 and third electrode finger 27 and the center-to-center distance between the adjacent second electrode finger 26 and third electrode finger 27. In this case, d/p is, for example, preferably less than or equal to about 0.5, more preferably less than or equal to about 0.24, where d is the thickness of the piezoelectric layer 14. This allows for better excitation of the thickness-shear mode bulk wave.

The acoustic wave devices of example embodiments of the present invention do not necessarily have to be configured to be able to use the thickness-shear mode. An acoustic wave device according to an example embodiment of the present invention may be configured to be able to excite a plate wave. In this case, the excitation region is the intersection region E illustrated in FIG. 2.

In the first example embodiment, the piezoelectric layer 14 is, for example, a LiNbO₃ layer. In this case, the fractional band width of the acoustic wave device 10 depends on the Euler angles (φ, θ, ψ) of the lithium niobate used in the piezoelectric layer 14. The fractional band width is expressed by (|fa−fr|/fr)×100[%], where fr is the resonant frequency and fa is the anti-resonant frequency.

The relationship between the fractional band width of the acoustic wave device 10 and the Euler angles (φ, θ, ψ) of the piezoelectric layer 14 when d/p is infinitely close to 0 is derived. Note that φ in the Euler angles is set to 0°.

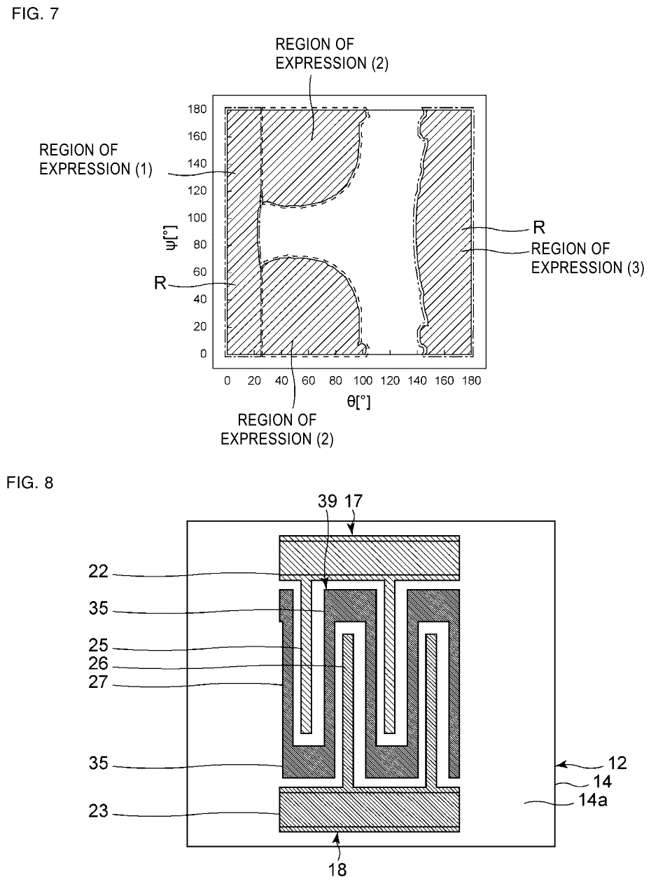

FIG. 7 is a diagram illustrating a map of a fractional band width with respect to the Euler angles (0°, θ, ψ) of LiNbO₃ when d/p is infinitely close to 0.

A hatched region R in FIG. 7 is a region where the fractional band width of at least more than or equal to 2% is obtained. The range of the region R is approximated by the following Expressions (1), (2), and (3). When φ in the Euler angles (φ, θ, ψ) is within the range of about 0°±10°, the relationship between θ and ψ and the fractional band width is the same as that illustrated in FIG. 7. Also in the case where the piezoelectric layer 14 is, for example, a lithium tantalate layer, the relationship between θ and ψ in the Euler angles (within the range of 0°±10°, θ, ψ) and the fractional band width is the same or substantially the same as that illustrated in FIG. 7.

(within the range of 0°±10°, 0° to 25°, any ψ) Expression (1)

(within the range of 0°±10°, 25° to 100°, 0° to 75°[(1−(θ−50)²/2500)]^{1/2} or 180°−75°[(1−(θ−50)²/2500)]^{1/2} to 180°) Expression (2)

(within the range of 0°±10°, 180°−40°[(1−(ψ−90)²/8100)]^{1/2} to 180°, any ψ) Expression (3)

It is preferable that the Euler angles are within the range of Expression (1), Expression (2), or Expression (3). This allows the fractional band width to be sufficiently widened, thus making it possible to suitably use the acoustic wave device 10 in a filter device.

As illustrated in FIG. 2, in the first example embodiment, the reference potential electrode 19 includes the third busbar 24 as a connection electrode and the plurality of third electrode fingers 27. The reference potential electrode 19 is a comb-shaped electrode. However, the reference potential electrode 19 does not have to be a comb-shaped electrode. For example, in a modification of the first example embodiment illustrated in FIG. 8, the reference potential electrode 39 has a meandering shape. In this modification, the insulating film 28 is not provided on the piezoelectric layer 14. The connection electrode 35 includes only a portion corresponding to the plurality of first connection electrodes 24A in the first example embodiment. The connection electrode 35 in this modification is not a third busbar.

More specifically, the reference potential electrode 39 includes a plurality of connection electrodes 35 located on the first busbar 22 side and a plurality of connection electrodes 35 located on the second busbar 23 side. The leading end portions of two adjacent third electrode fingers 27 on the first busbar 22 side or the leading end portions of two adjacent third electrode fingers 27 on the second busbar 23 side are connected to each other by the connection electrode 35. For example, among the plurality of third electrode fingers 27, the third electrode fingers 27 other than those at both ends in the electrode finger orthogonal direction have respective connection electrodes 35 connected to the leading end portions on the first busbar 22 side and the leading end portions on the second busbar 23 side. Each third electrode finger 27 is connected to its neighboring third electrode fingers 27 by the connection electrodes 35. By repeating this structure, the reference potential electrode 39 is configured into a meandering shape.

It is possible also in this modification to achieve the miniaturization of a filter device, as in the first example embodiment. In addition, the plurality of electrode fingers are arranged in the same or substantially the same manner as in the first example embodiment. Specifically, the center-to-center distance between the adjacent first electrode finger 25 and second electrode finger 26 is constant in the first comb-shaped electrode 17 and the second comb-shaped electrode 18. In the reference potential electrode 39, the plurality of third electrode fingers 27 are arranged equally or substantially equally spaced apart. The center-to-center distance between the adjacent first electrode finger 25 and third electrode finger 27 and the center-to-center distance between the adjacent second electrode finger 26 and third electrode finger 27 are not constant. This makes it possible to reduce or prevent degradation of the filter characteristics. Specifically, it is possible to reduce or prevent reduction in steepness on the low-frequency side of the pass band.

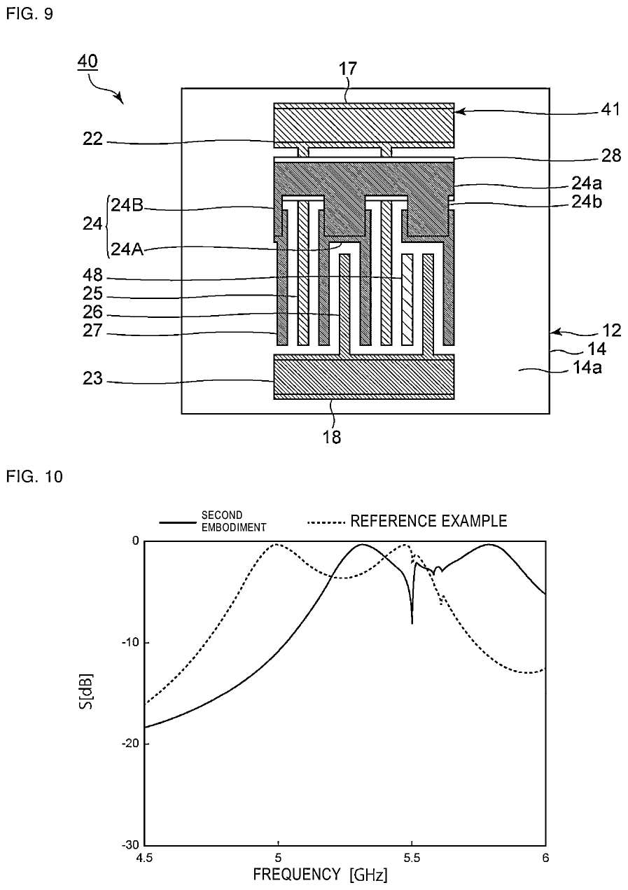

FIG. 9 is a schematic plan view of an acoustic wave device according to a second example embodiment of the present invention.

The present example embodiment differs from the first example embodiment in that the plurality of electrode fingers include a plurality of fourth electrode fingers 48 and the plurality of electrode fingers are arranged equally or substantially equally spaced apart. The fourth electrode finger 48 is a floating electrode. The floating electrode is an electrode that is not connected to any of the input potential, output potential, and reference potential. Otherwise, an acoustic wave device 40 of the present example embodiment has the same or substantially the same configuration as that of the acoustic wave device 10 of the first example embodiment.

A functional electrode 41 of the acoustic wave device 40 is configured such that at least one of the plurality of third electrode fingers 27 in the reference example illustrated in FIG. 4 is replaced with the fourth electrode finger 48. More specifically, as illustrated in FIG. 9, the third electrode finger 27 or the fourth electrode finger 48 is located between the first electrode finger 25 and the second electrode finger 26.

The acoustic wave device of the present example embodiment may be configured such that at least one of the plurality of first electrode fingers 25 or the plurality of second electrode fingers 26 in the reference example is replaced with the fourth electrode finger 48.

In a region where the fourth electrode finger 48 is not provided, the order in which the plurality of electrode fingers are arranged is the same as in the first example embodiment and the reference example. Specifically, the order is such that, starting from the first electrode finger 25, the first electrode finger 25, the third electrode finger 27, the second electrode finger 26, and the third electrode finger 27 define one period. However, in a region corresponding to the configuration in which the third electrode finger 27 is replaced with the fourth electrode finger 48, the order in which the electrode fingers are arranged is not the above order.

In the present example embodiment, the first electrode finger 25, the second electrode finger 26, the third electrode finger 27, and the fourth electrode finger 48 are arranged equally or substantially equally spaced apart. Therefore, the center-to-center distance between the adjacent first electrode finger 25 and third electrode finger 27 and the center-to-center distance between the adjacent second electrode finger 26 and third electrode finger 27 are constant.

The present example embodiment includes the following configuration. 1) The functional electrode 41 is provided on the piezoelectric layer 14 and includes at least one fourth electrode finger 48 adjacent to the first electrode finger 25, the second electrode finger 26, or the third electrode finger 27. 2) The fourth electrode finger 48 is a floating electrode. This makes it possible to achieve miniaturization of a filter device and suppress degradation of the filter characteristics. Specifically, the pass band frequency can be adjusted without significantly changing the band width from a desired band width. This will be specifically described by comparing the second example embodiment and the reference example.

The design parameters of the acoustic wave device 40 having the configuration of the second example embodiment are as follows. The design parameters in the reference example are the same or substantially the same as those in the second example embodiment, except for the fourth electrode finger 48.

### Piezoelectric Layer

Material: LiNbO₃
Euler angles (φ, θ, ψ): (0°, 0°, 90°)
Thickness: about 400 nm

### First to Third Electrode Fingers

Layer structure: Ti layer/AlCu layer/Ti layer from the piezoelectric layer side
Thickness of each layer: about 10 nm/about 390 nm/about 4 nm from the piezoelectric layer side
Order of the first to third electrode fingers expressed by the potential to be connected: IN, GND, OUT, and GND are repeated in this order.
Center-to-center distance between first electrode finger and second electrode finger: about 2.8 μm
Duty ratio of functional electrode: about 0.3

FIG. 10 is a graph illustrating bandpass characteristics of the acoustic wave devices according to the second example embodiment and the reference example.

As illustrated in FIG. 10, the pass band frequencies are different between the second example embodiment and the reference example. Furthermore, the band width in the second example embodiment is not significantly different from that in the reference example.

When the acoustic wave device 40 of the second example embodiment is used as an acoustic wave resonator in a filter device, a filter waveform can be suitably obtained even when the filter device includes only one or a small number of acoustic wave resonators. As described above, in the second example embodiment, the miniaturization of the filter device can be achieved, and the frequency can be adjusted without significantly changing the band width.

The fourth electrode finger 48 may be adjacent to the first electrode finger 25, the second electrode finger 26, or the third electrode finger 27. A first modification and a second modification of the second example embodiment will be described below, which differ from the second example embodiment only in the arrangement of the fourth electrode finger 48. It is possible also in the first modification and the second modification to achieve the miniaturization of a filter device and reduce or prevent degradation of the filter characteristics, as in the second example embodiment.

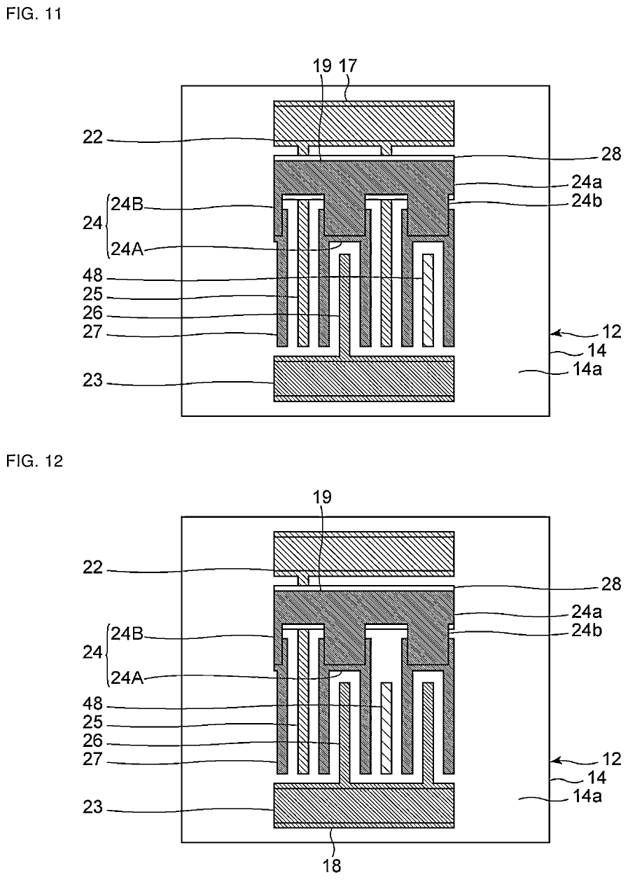

In a configuration of the first modification illustrated in FIG. 11, at least one of the plurality of second electrode fingers 26 in the reference example illustrated in FIG. 4 is replaced with a fourth electrode finger 48. In a region where the fourth electrode finger 48 is not provided, the order in which the plurality of electrode fingers are arranged is the same as in the first example embodiment and the reference example. Specifically, the order is such that, starting from the first electrode finger 25, the first electrode finger 25, the third electrode finger 27, the second electrode finger 26, and the third electrode finger 27 define one period. However, in a region corresponding to the configuration in which the second electrode finger 26 is replaced with the fourth electrode finger 48, the order in which the electrode fingers are arranged is not the above order.

The fourth electrode finger 48 is located between two third electrode fingers 27. Therefore, the fourth electrode finger 48 is adjacent to the third electrode finger 27. The plurality of electrode fingers are arranged equally or substantially equally spaced apart also in this modification.

In a configuration of the second modification illustrated in FIG. 12, at least one of the plurality of first electrode fingers 25 in the reference example illustrated in FIG. 4 is replaced with a fourth electrode finger 48. In a region where the fourth electrode finger 48 is not provided, the order in which the plurality of electrode fingers are arranged is the same as in the first example embodiment and the reference example. However, in a region corresponding to the configuration in which the first electrode finger 25 is replaced with the fourth electrode finger 48, the order in which the electrode fingers are arranged is different from that in the first example embodiment and the reference example.

The fourth electrode finger 48 is located between two third electrode fingers 27. Therefore, the fourth electrode finger 48 is adjacent to the third electrode finger 27. The plurality of electrode fingers are arranged equally or substantially equally spaced apart also in this modification.

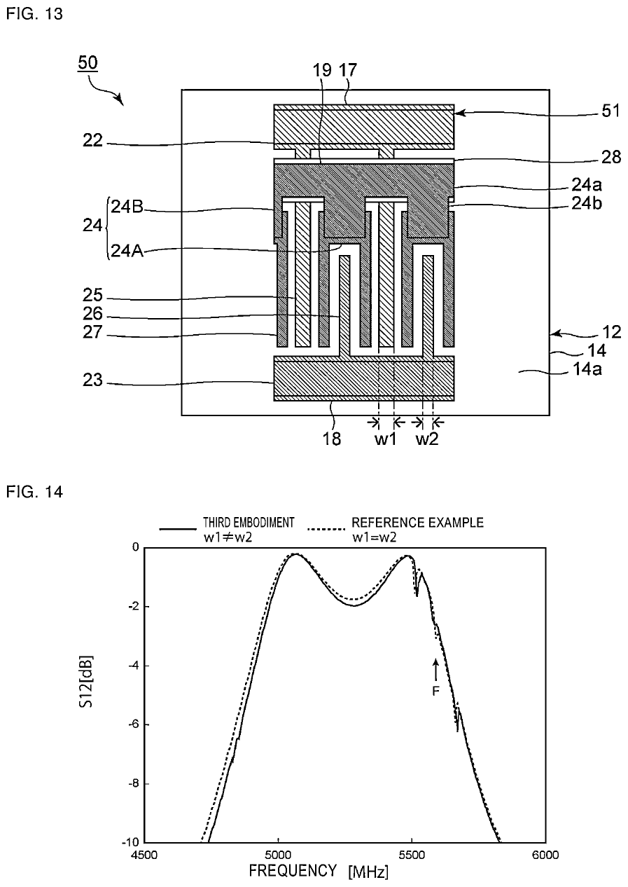

FIG. 13 is a schematic plan view of an acoustic wave device according to a third example embodiment of the present invention.

The third example embodiment differs from the first example embodiment in that w1≠w2, where w1 is the width of the first electrode finger 25 and w2 is the width of the second electrode finger 26. The present example embodiment also differs from the first example embodiment in that a plurality of electrode fingers are arranged equally or substantially equally spaced apart. Otherwise, an acoustic wave device 50 of the present example embodiment has the same or substantially the same configuration as that of the acoustic wave device 10 of the first example embodiment.

A functional electrode 51 of the acoustic wave device 50 has a configuration in which the width w1 of the plurality of first electrode fingers 25 in the reference example illustrated in FIG. 4 is wider than the width w2 of the plurality of second electrode fingers 26. However, the width w2 of the plurality of second electrode fingers 26 may be wider than the width w1 of the plurality of first electrode fingers 25.

The present example embodiment is configured such that w1≠w2. This makes it possible to achieve miniaturization of a filter device and reduce or prevent degradation of the filter characteristics. Specifically, it is possible to reduce or prevent ripple in the filter characteristics caused by unwanted waves. This will be described below by comparing the third example embodiment and the reference example.

The design parameters of the acoustic wave device 50 having the configuration of the third example embodiment are as follows. The design parameters in the reference example are the same or substantially the same as those in the third example embodiment, except for the width of the electrode fingers.

### Piezoelectric Layer

Material: LiNbO₃
Euler angles (φ, θ, ψ): (0°, 0°, 90°)
Thickness: about 400 nm

### First to Third Electrode Fingers

Layer structure: Ti layer/AlCu layer/Ti layer from the piezoelectric layer side
Thickness of each layer: about 10 nm/about 390 nm/about 4 nm from the piezoelectric layer side
Order of the first to third electrode fingers expressed by the potential to be connected: IN, GND, OUT, and GND are repeated in this order.
Center-to-center distance between first electrode finger and second electrode finger: about 2.8 μm
Duty ratio of functional electrode: about 0.3

FIG. 14 is a graph illustrating bandpass characteristics of the acoustic wave devices according to the third example embodiment and the reference example.

As indicated by an arrow F in FIG. 14, the ripple caused by the unwanted waves can be reduced or prevented in the third example embodiment compared to the reference example. In the third example embodiment, since w1≠w2, the frequency at which the unwanted waves occur can be dispersed. This makes it possible to reduce or prevent the unwanted waves.

When the acoustic wave device 50 of the third example embodiment is used as an acoustic wave resonator in a filter device, a filter waveform can be suitably obtained even when the filter device includes only one or a small number of acoustic wave resonators. As described above, in the third example embodiment, the miniaturization of the filter device can be achieved, and the unwanted waves can be reduced or prevented.

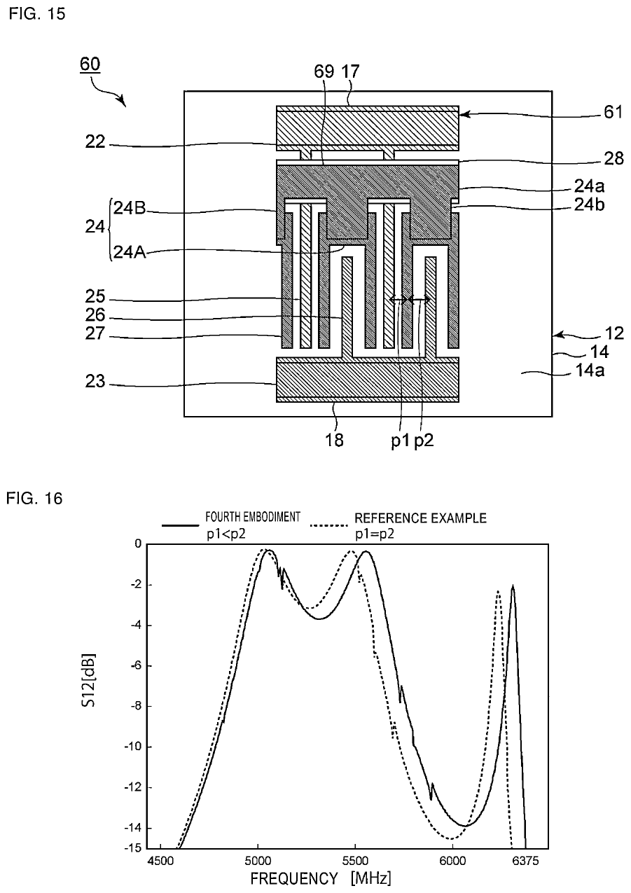

FIG. 15 is a schematic plan view of an acoustic wave device according to a fourth example embodiment of the present invention.

The present example embodiment differs from the first example embodiment in that the interval between a plurality of third electrode fingers 27 in a reference potential electrode 69 of a functional electrode 61 is not constant. Otherwise, an acoustic wave device 60 of the present example embodiment has the same or substantially the same configuration as that of the acoustic wave device 10 of the first example embodiment.

More specifically, among the adjacent third electrode fingers 27, the center-to-center distance between the third electrode fingers 27 connected by a first connection electrode 24A is different from the center-to-center distance between the third electrode fingers 27 not connected by the first connection electrode 24A. The center-to-center distance between the third electrode fingers 27 connected by the first connection electrode 24A among the adjacent third electrode fingers 27 is constant. Similarly, the center-to-center distance between the third electrode fingers 27 not connected by the first connection electrode 24A among the adjacent third electrode fingers 27 is constant.

As illustrated in FIG. 15, in a first comb-shaped electrode 17 and a second comb-shaped electrode 18, the center-to-center distance between the adjacent first electrode finger 25 and second electrode finger 26 is constant.

In the present example embodiment, p1≈p2, where p1 is the center-to-center distance between the adjacent first electrode finger 25 and third electrode finger 27 and p2 is the center-to-center distance between the adjacent second electrode finger 26 and third electrode finger 27. Specifically, p1<p2. However, p1<p2 may also hold true.

p1 is constant in each portion where the first electrode finger 25 and the third electrode finger 27 are adjacent to each other. Similarly, p2 is constant in each portion where the second electrode finger 26 and the third electrode finger 27 are adjacent to each other.

The present example embodiment is configured to have the following configuration. 1) In the first comb-shaped electrode 17 and the second comb-shaped electrode 18, the center-to-center distance between the adjacent first electrode fingers 25 and the center-to-center distance between the adjacent second electrode fingers 26 are constant. 2) In the reference potential electrode 69, the center-to-center distance between the adjacent third electrode fingers 27 is not constant. 3) p1≠p2. This makes it possible to achieve miniaturization of a filter device and change the frequency without significant degradation of the filter characteristics. This will be described below by comparing the fourth example embodiment and the reference example illustrated in FIG. 4.

The design parameters of the acoustic wave device 60 having the configuration of the fourth example embodiment are as follows. The design parameters in the reference example are the same or substantially the same as those in the fourth example embodiment, except for the center-to-center distance between the adjacent electrode fingers.

### Piezoelectric Layer

Material: LiNbO₃
Euler angles (φ, θ, ψ): (0°, 0°, 90°)
Thickness: about 400 nm

### First to Third Electrode Fingers

Layer structure: Ti layer/AlCu layer/Ti layer from the piezoelectric layer side
Thickness of each layer: about 10 nm/about 390 nm/about 4 nm from the piezoelectric layer side
Order of the first to third electrode fingers expressed by the potential to be connected: IN, GND, OUT, and GND are repeated in this order.
Center-to-center distance between first electrode finger and second electrode finger: about 2.8 μm
Duty ratio of functional electrode: about 0.3

The comparison is made in both cases where the relationship between the center-to-center distance p1 and the center-to-center distance p2 in the fourth example embodiment is p1<p2 and where p1>p2.

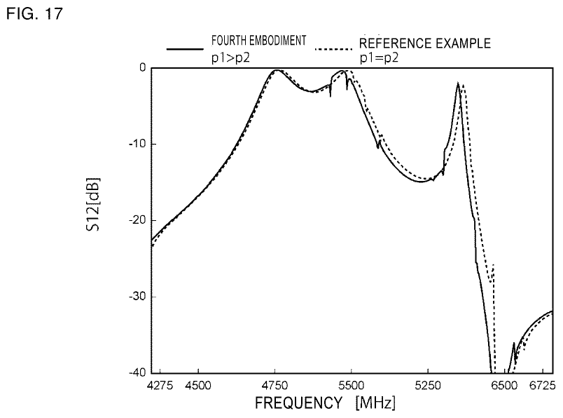

FIG. 16 is a graph illustrating bandpass characteristics of the acoustic wave devices according to the fourth example embodiment where p1<p2 and the reference example where p1=p2. FIG. 17 is a graph illustrating bandpass characteristics of the acoustic wave devices according to the fourth example embodiment where p1>p2 and the reference example where p1=p2.

As illustrated in FIG. 16, the pass band of the fourth example embodiment is located on the slightly higher frequency side than the pass band of the reference example, and also has a larger value of the fractional band width. The fractional band width is expressed by (|fa−fr|/fr)×100[%] as described above. Compared to the case where p1=p2, when only the center-to-center distance p2 is increased, the pass band frequency becomes lower in a filter device including a general surface acoustic wave resonator. On the other hand, in an acoustically coupled filter as in the fourth example embodiment, the pass band frequency becomes higher when p1<p2.

As illustrated in FIG. 17, the pass band of the fourth example embodiment is located on the slightly lower frequency side than the pass band of the reference example, and also has a smaller value of the fractional band width. Compared to the case where p1=p2, when only the center-to-center distance p2 is shortened, the pass band frequency becomes higher in a filter device using a general surface acoustic wave resonator. On the other hand, in an acoustically coupled filter as in the fourth example embodiment, the pass band frequency becomes lower when p1>p2. In the fourth example embodiment, the pass band frequency and the fractional band width can be adjusted by adjusting the center-to-center distance p1 and the center-to-center distance p2.

When the acoustic wave device 60 of the fourth example embodiment is provided as an acoustic wave resonator in a filter device, a filter waveform can be suitably obtained even when the filter device includes only one or a small number of acoustic wave resonators. This makes it possible, in the fourth example embodiment, to achieve miniaturization of the filter device and change the frequency without significant degradation of the filter characteristics.

The thickness-shear mode will be described in detail below using an example where the functional electrode is an IDT electrode. The IDT electrode includes no third electrode fingers. The “electrode” in the IDT electrode described below corresponds to the electrode finger. A support in the following example corresponds to the support substrate. The reference potential may be hereinafter referred to as a ground potential.

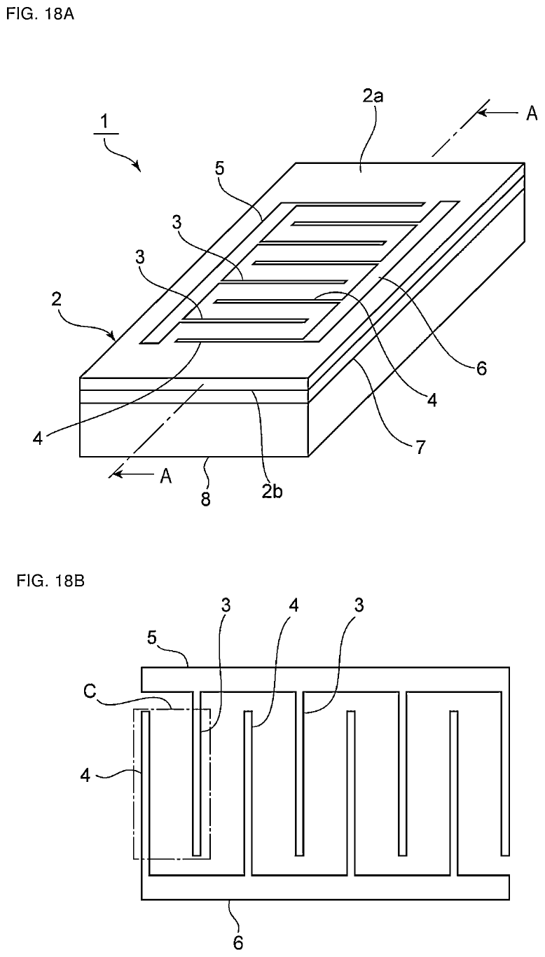

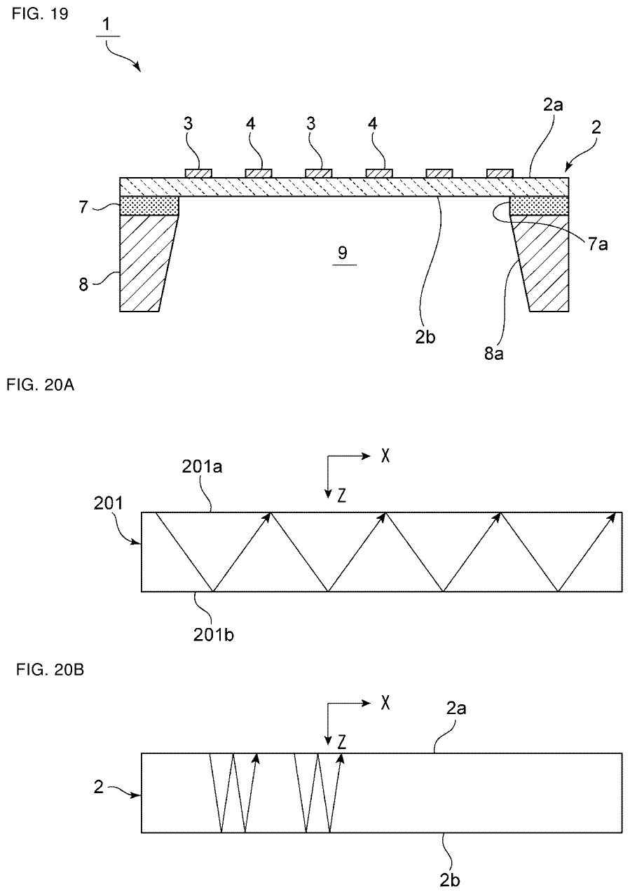

FIG. 18A is a schematic perspective view illustrating an appearance of an acoustic wave device that excites a thickness-shear mode bulk wave. FIG. 18B is a plan view illustrating an electrode structure on a piezoelectric layer. FIG. 19 is a cross-sectional view of a portion taken along line A-A in FIG. 18A.

An acoustic wave device 1 includes a piezoelectric layer 2 made of, for example, LiNbO₃. The piezoelectric layer 2 may be made of, for example, LiTaO₃. The cut-angle of LiNbO₃ or LiTaO₃ is a Z-cut in the present example embodiment, but may be a rotated Y-cut or X-cut. The thickness of the piezoelectric layer 2 is not particularly limited, but is, for example, preferably more than or equal to about 40 nm and less than or equal to about 1000 nm, and more preferably more than or equal to about 50 nm and less than or equal to about 1000 nm in order to effectively excite a thickness-shear mode. The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 18A and 18B, a plurality of the electrodes 3 are connected to a first busbar 5. A plurality of the electrodes 4 are connected to a second busbar 6. The plurality of electrodes 3 and the plurality of electrodes 4 are interdigitated with each other. The electrode 3 and the electrode 4 have a rectangular or substantially rectangular shape and have a length direction. In a direction orthogonal or substantially orthogonal to the length direction, the electrode 3 and the electrode 4 adjacent thereto face each other. The length direction of the electrodes 3 and 4 and the direction orthogonal or substantially orthogonal to the length direction of the electrodes 3 and 4 each are a direction intersecting a thickness direction of the piezoelectric layer 2. Therefore, it can also be said that the electrode 3 and the electrode 4 adjacent thereto face each other in the direction intersecting the thickness direction of the piezoelectric layer 2. The length direction of the electrodes 3 and 4 may be replaced with the direction orthogonal or substantially orthogonal to the length direction of the electrodes 3 and 4 illustrated in FIGS. 18A and 18B. That is, the electrodes 3 and 4 may extend in the direction in which the first busbar 5 and the second busbar 6 extend in FIGS. 18A and 18B. In this case, the first busbar 5 and the second busbar 6 extend in the direction in which the electrodes 3 and 4 extend in FIGS. 18A and 18B. A plurality of pairs of structures in which the electrode 3 connected to one potential and the electrode 4 connected to the other potential are adjacent to each other are provided in the direction orthogonal or substantially orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other, but to a case where the electrode 3 and the electrode 4 are arranged with an interval therebetween. When the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be, for example, 1.5 pairs, 2.5 pairs, or the like. The center-to-center distance between the electrodes 3 and 4, that is, the pitch is preferably in the range of, for example, more than or equal to about 1 μm and less than or equal to about 10 μm. In addition, the width of the electrodes 3 and 4, that is, the dimension of the electrodes 3 and 4 in their facing direction, is, for example, preferably in the range of more than or equal to about 50 nm and less than or equal to about 1000 nm, and more preferably in the range of more than or equal to about 150 nm and less than or equal to about 1000 nm. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to the polarization direction of the piezoelectric layer 2. This does not apply when a piezoelectric body of another cut-angle is used as the piezoelectric layer 2. Here, the term “orthogonal” is not limited to strictly orthogonal but may be substantially orthogonal (an angle between the direction orthogonal to the length direction of the electrodes 3 and 4 and the polarization direction is, for example, about 90°±10°).

A support 8 is laminated on the second main surface 2b side of the piezoelectric layer 2 with an insulating layer 7 interposed therebetween. The insulating layer 7 and the support 8 have a frame shape and include through-holes 7a and 8a as illustrated in FIG. 19. A cavity 9 is thus provided. The cavity 9 is provided so as not to interfere with the vibration of an excitation region C of the piezoelectric layer 2. Therefore, the support 8 is laminated on the second main surface 2b with the insulating layer 7 interposed therebetween at a position not overlapping with a portion where at least a pair of electrodes 3 and 4 are provided. The insulating layer 7 need not be provided. Therefore, the support 8 can be directly or indirectly laminated on the second main surface 2b of the piezoelectric layer 2.

The insulating layer 7 is made of, for example, silicon oxide. However, the insulating layer 7 can be made of an appropriate insulating material such as, for example, silicon oxynitride or alumina in addition to silicon oxide. The support 8 is made of, for example, Si. The plane orientation of the surface of Si on the piezoelectric layer 2 side may be (100), (110), or (111). Preferably, for example, high-resistance Si of the support 8 has a resistivity of more than or equal to about 4 kΩ cm. However, the support 8 can also be made using an appropriate insulating material or semiconductor material.

Examples of the material of the support 8 include piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, semiconductors such as gallium nitride, and the like.

The plurality of electrodes 3 and 4 and the first and second busbars 5 and 6 are made of an appropriate metal or alloy such as, for example, Al or an AlCu alloy. In the acoustic wave device 1, the electrodes 3 and 4 and the first and second busbars 5 and 6 have, for example, a structure in which an Al film is laminated on a Ti film. A close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the thickness-shear mode excited in the piezoelectric layer 2. In the acoustic wave device 1, for example, d/p is less than or equal to about 0.5, where d is the thickness of the piezoelectric layer 2, and p is the center-to-center distance between any adjacent electrodes 3 and 4 of the plurality of pairs of electrodes 3 and 4. Therefore, the bulk wave in the thickness-shear mode is effectively excited, and good resonance characteristics can be obtained. More preferably, for example, d/p is less than or equal to about 0.24, in which case even better resonance characteristics can be obtained.

Since the acoustic wave device 1 has the configuration described above, even when the number of pairs of the electrodes 3 and 4 is reduced in an attempt for miniaturization, Q value is not easily reduced. This is because the propagation loss is small even if the number of electrode fingers in the reflectors on both sides is reduced. In addition, the reason why the number of electrode fingers can be reduced is that the bulk wave in the thickness-shear mode is used. The difference between a Lamb wave used in an acoustic wave device and the thickness-shear mode bulk wave described above will be described with reference to FIGS. 20A and 20B.

FIG. 20A is a schematic elevational cross-sectional view for explaining a Lamb wave propagating through a piezoelectric film of an acoustic wave device as described in Japanese Unexamined Patent Application Publication No. 2012-257019. As illustrated in FIG. 20A, a wave propagates through a piezoelectric film 201 as indicated by arrows. Here, the piezoelectric film 201 includes a first main surface 201a and a second main surface 201b, which face each other, and a thickness direction connecting the first main surface 201a and the second main surface 201b is the Z direction. The X direction is a direction in which electrode fingers of an IDT electrode are arranged. As illustrated in FIG. 20A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 20B, in the acoustic wave device 1, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, propagation loss does not easily occur even when the number of electrode fingers of the reflector is reduced. Furthermore, even when the number of pairs of electrodes including the electrodes 3 and 4 is reduced in an attempt to achieve miniaturization, the Q value is not easily reduced.

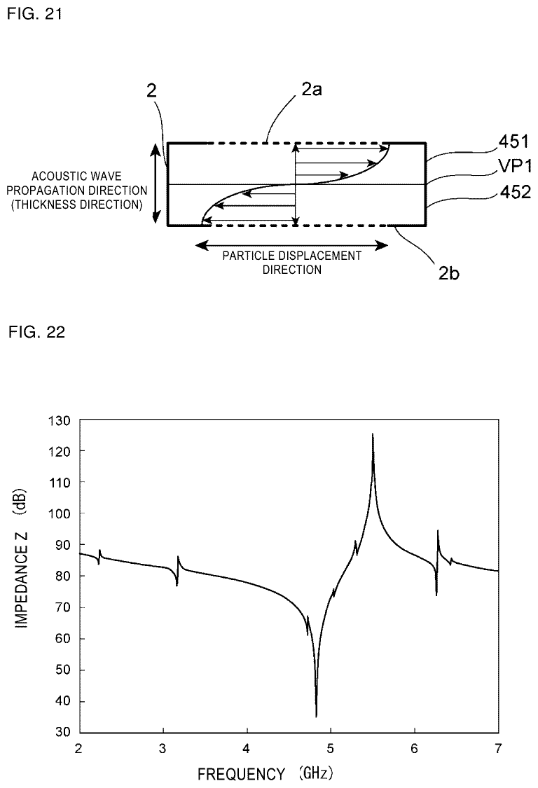

As illustrated in FIG. 21, the amplitude direction of the bulk wave in the thickness-shear mode in a first region 451 included in the excitation region C of the piezoelectric layer 2 is the opposite in a second region 452 included in the excitation region C. FIG. 21 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal or substantially orthogonal to the thickness direction of the piezoelectric layer 2 and divides the piezoelectric layer 2 into two portions in the excitation region C. The second region 452 is a region between the virtual plane VP1 and the second main surface 2b in the excitation region C.

As described above, in the acoustic wave device 1, at least a pair of electrodes including the electrode 3 and the electrode 4 are arranged. However, since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In the acoustic wave device 1, as described above, at least a pair of electrodes are the electrode connected to the hot potential or the electrode connected to the ground potential, and a floating electrode is not provided.

FIG. 22 is a graph illustrating resonance characteristics of the acoustic wave device illustrated in FIG. 19. The design parameters of the acoustic wave device 1 having the resonance characteristics are as follows.
Piezoelectric layer 2: LiNbO₃ with Euler angles (0°, 0°, 90°)
Thickness: about 400 nm
Length of region where electrodes 3 and 4 overlap as seen in direction orthogonal to length direction of electrodes 3 and 4, that is, excitation region C: about 40 μm
Number of pairs of electrodes consisting of electrodes 3 and 4: 21 pairs
Center-to-center distance between electrodes: about 3 μm
Width of electrodes 3 and 4: about 500 nm
d/p: about 0.133
Insulating layer 7: silicon oxide film with thickness of about 1 μm
Support 8: Si

The length of the excitation region C is a dimension of the excitation region C along the length direction of the electrodes 3 and 4.

In the acoustic wave device 1, the electrode-to-electrode distances of the electrode pairs including the electrodes 3 and 4 are all equal or substantially equal in the plurality of pairs. That is, the electrodes 3 and the electrodes 4 are arranged with equal or substantially equal pitches.

As is clear from FIG. 22, good resonance characteristics with the fractional band width of about 12.5% are obtained even though no reflector is provided.

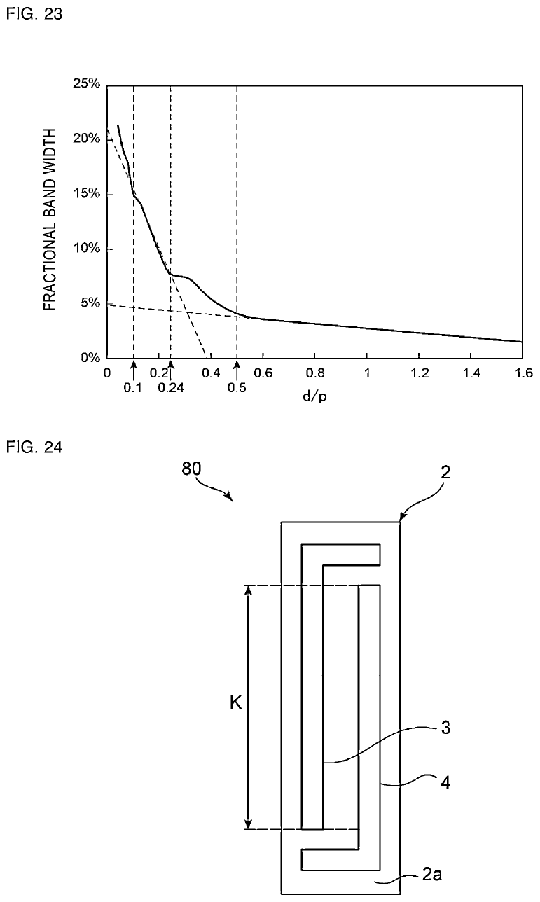

As described above, in the acoustic wave device 1, for example, d/p is less than or equal to about 0.5, more preferably less than or equal to about 0.24, where d is the thickness of the piezoelectric layer 2 and p is the center-to-center distance between the electrode 3 and the electrode 4. This will be described with reference to FIG. 23.

A plurality of acoustic wave devices are obtained in the same manner as the acoustic wave device having the resonance characteristics illustrated in FIG. 22, except that d/p is changed. FIG. 23 is a graph illustrating a relationship between d/p and the fractional band width of the acoustic wave device as a resonator.

As is clear from FIG. 23, when d/p>about 0.5, the fractional band width is less than about 5% even if d/p is adjusted. On the other hand, when d/p≤about 0.5, the fractional band width can be set to more than or equal to about 5% by changing d/p within that range, that is, a resonator with a high coupling coefficient can be configured. Furthermore, when d/p is less than or equal to about 0.24, the fractional band width can be increased to more than or equal to about 7%. In addition, by adjusting d/p within this range, a resonator with an even wider fractional band width can be obtained, and a resonator with an even higher coupling coefficient can be obtained. Therefore, it can be seen that, by setting d/p to less than or equal to about 0.5, a resonator with a high coupling coefficient can be provided using the thickness-shear mode bulk wave.

FIG. 24 is a plan view of an acoustic wave device that uses a thickness-shear mode bulk wave. In an acoustic wave device 80, a pair of electrodes, including an electrode 3 and an electrode 4, are provided on a first main surface 2a of a piezoelectric layer 2. K in FIG. 24 is an intersection width. As described above, in an acoustic wave device according to an example embodiment of the present invention, the number of pairs of electrodes may be one. Even in this case, for example, when the d/p is less than or equal to about 0.5, the thickness-shear mode bulk wave can be effectively excited.

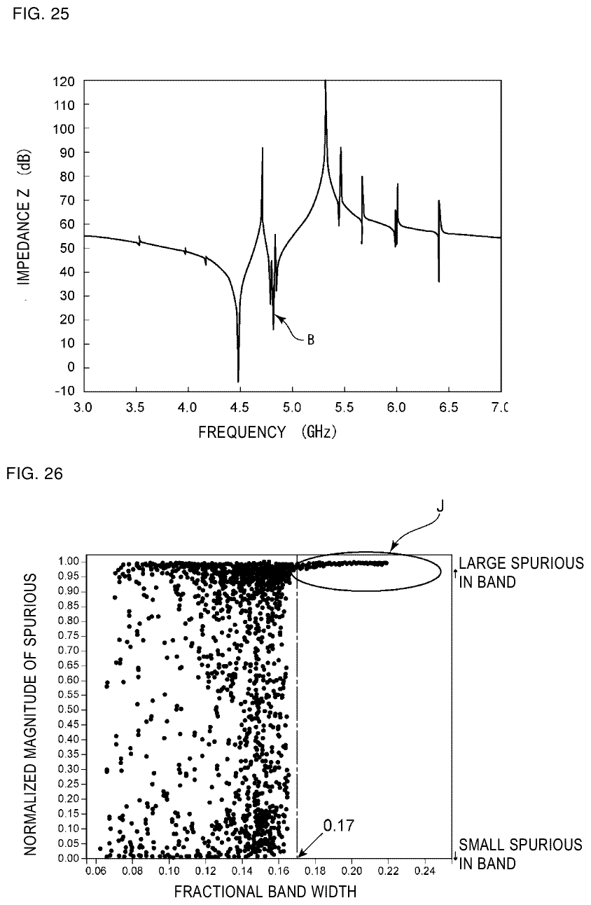

In the acoustic wave device 1, it is preferable that a metallization ratio MR of any adjacent electrodes 3 and 4 of the plurality of electrodes 3 and 4 with respect to the excitation region C, which is a region where the adjacent electrodes 3 and 4 overlap when viewed in their facing direction, satisfies MR≤about 1.75(d/p)+0.075. In that case, a spurious response can be effectively reduced. This will be described with reference to FIGS. 25 and 26. FIG. 25 is a reference diagram illustrating an example of the resonance characteristics of the acoustic wave device 1. A spurious response indicated by an arrow B appears between a resonant frequency and an anti-resonant frequency. Note that d/p=about 0.08 and the Euler angles of LiNbO₃ are (0°, 0°, 90°). The metallization ratio MR is about 0.35.

The metallization ratio MR will be described with reference to FIG. 18B. In the electrode structure of FIG. 18B, when focusing on a pair of electrodes 3 and 4, it is assumed that only this pair of electrodes 3 and 4 is provided. In this case, a portion surrounded by a dashed-dotted line is the excitation region C. When the electrode 3 and the electrode 4 are viewed in the direction orthogonal to the length direction of the electrodes 3 and 4, that is, in their facing direction, the excitation region C is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region C is the metallization ratio MR. That is, the metallization ratio MR is the ratio of the area of the metallization portion to the area of the excitation region C.

When a plurality of pairs of electrodes are provided, the ratio of the metallization portion included in the entire excitation region to the total area of the excitation region may be MR.

FIG. 26 is a diagram illustrating a relationship between a fractional band width and a phase rotation amount of the spurious impedance normalized by about 180 degrees as the magnitude of the spurious when a large number of acoustic wave resonators are configured according to the configuration of the acoustic wave device 1. The fractional band width is adjusted by changing the film thickness of the piezoelectric layer and the dimensions of the electrodes. FIG. 26 illustrates the results when a Z-cut LiNbO₃ piezoelectric layer is used, but the same tendency is obtained also when piezoelectric layers with other cut-angles are used.

In a region surrounded by an ellipse J in FIG. 26, the spurious response is as large as about 1.0. As is clear from FIG. 26, when the fractional band width exceeds about 0.17, that is, exceeds about 17%, a large spurious response with a spurious level of more than or equal to about 1 appears in a pass band even when the parameters defining the fractional band width are changed. That is, as in the resonance characteristics illustrated in FIG. 25, a large spurious response indicated by the arrow B appears within the band. Therefore, the fractional band width is, for example, preferably less than or equal to about 17%. In this case, the spurious response can be reduced by adjusting the film thickness of the piezoelectric layer 2, the dimensions of the electrodes 3 and 4, or the like.

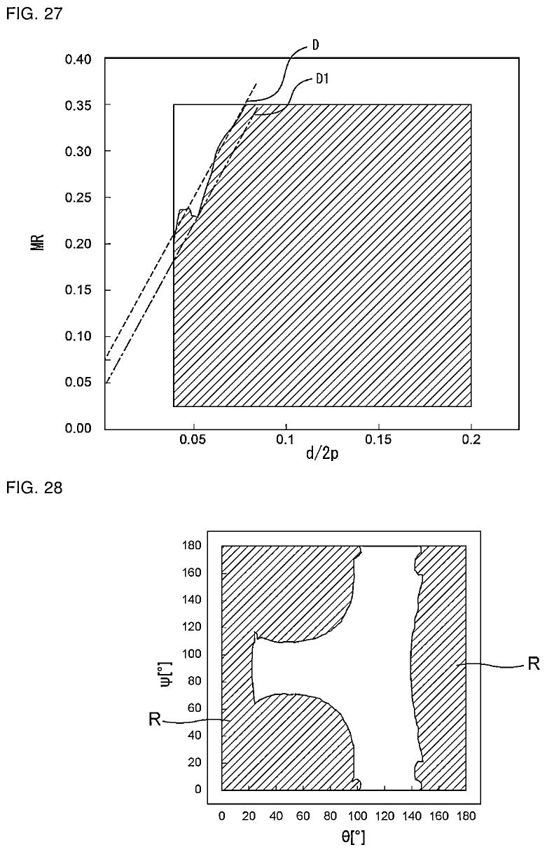

FIG. 27 is a diagram illustrating a relationship among d/2p, the metallization ratio MR, and the fractional band width. In the acoustic wave device, various acoustic wave devices having different values of d/2p and different values of MR are provided, and the fractional band width is measured. A hatched portion to the right of a dashed line D illustrated in FIG. 27 is a region where the fractional band width is less than or equal to about 17%. The boundary between the hatched region and the non-hatched region is represented by MR=about 3.5 (d/2p)+0.075. That is, MR=about 1.75(d/p)+0.075. Therefore, for example, MR 5 about 1.75(d/p)+0.075 is preferably satisfied. In this case, the fractional band width is easily set to less than or equal to about 17%. More preferably, for example, it is the region in FIG. 27 to the right of a dashed-dotted line D1 indicating MR=about 3.5(d/2p)+0.05. That is, when MR≤about 1.75(d/p)+0.05, the fractional band width can be reliably set to less than or equal to about 17%.

FIG. 28 is a diagram illustrating a map of the fractional band width with respect to the Euler angles (0°, θ, ψ) of LiNbO₃ when d/p is infinitely close to 0. A plurality of hatched regions R illustrated in FIG. 28 are regions where the fractional band width of more than or equal to about 2% is obtained. When φ in the Euler angles (φ, θ, ψ) is within the range of about 0°+5°, the relationship between θ and ψ and the fractional band width is the same as that illustrated in FIG. 28. Also when the piezoelectric layer is made of lithium tantalate (LiTaO₃), the relationship between θ and ψ in the Euler angles (within the range of 0°+5°, θ, ψ) and BW is the same or substantially the same as that illustrated in FIG. 28.

Therefore, when φ in the Euler angles (φ, θ, ψ) of the lithium niobate or lithium tantalate of the piezoelectric layer is within the range of 0°+5° and θ and φ are within the range of any of the regions R illustrated in FIG. 28, the fractional band width can be sufficiently widened, which is preferable.

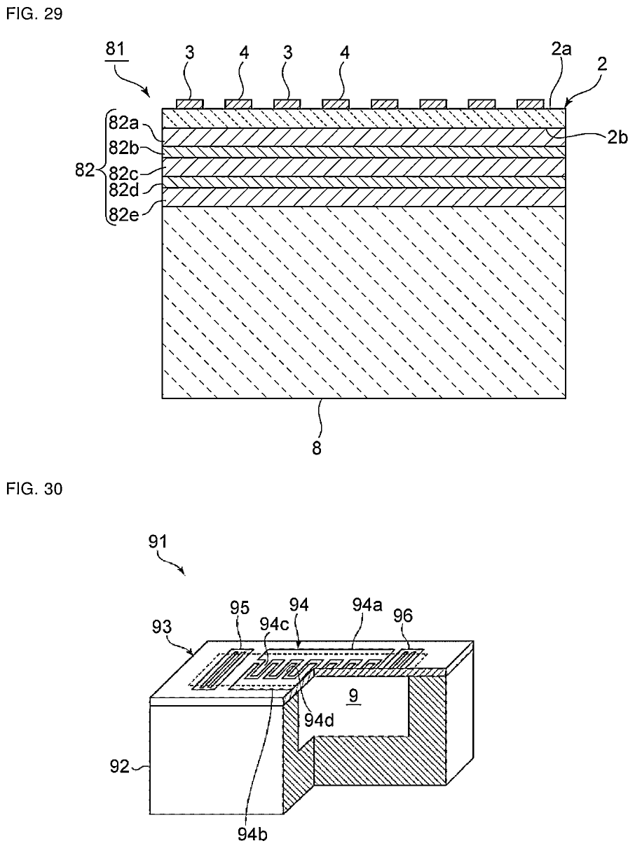

FIG. 29 is an elevational cross-sectional view of an acoustic wave device including an acoustic multilayer film.

In an acoustic wave device 81, an acoustic multilayer film 82 is laminated on a second main surface 2b of a piezoelectric layer 2. The acoustic multilayer film 82 has a multilayer structure including low acoustic impedance layers 82a, 82c, and 82e with a relatively low acoustic impedance and high acoustic impedance layers 82b and 82d with a relatively high acoustic impedance. Using the acoustic multilayer film 82 makes it possible to confine the thickness-shear mode bulk wave in the piezoelectric layer 2 without using the cavity 9 in the acoustic wave device 1. In the acoustic wave device 81, resonance characteristics based on the thickness-shear mode bulk wave can be obtained by setting the above d/p to less than or equal to about 0.5. In the acoustic multilayer film 82, the number of the low acoustic impedance layers 82a, 82c, and 82e and high acoustic impedance layers 82b and 82d laminated is not particularly limited. It is sufficient that at least one high acoustic impedance layer 82b or 82d is disposed farther from the piezoelectric layer 2 than the low acoustic impedance layers 82a, 82c, and 82e.

The low acoustic impedance layers 82a, 82c, and 82e and the high acoustic impedance layers 82b and 82d can be made of any appropriate material as long as the above acoustic impedance relationship is satisfied. Examples of the material of the low acoustic impedance layers 82a, 82c, and 82e include silicon oxide or silicon oxynitride, and the like. For example, alumina, silicon nitride, metal or the like can be used as the material of the high acoustic impedance layers 82b and 82d.

FIG. 30 is a partially cutaway perspective view for explaining an acoustic wave device that uses a Lamb wave.

An acoustic wave device 91 includes a support substrate 92. The support substrate 92 includes a recessed portion that is open on its upper surface. A piezoelectric layer 93 is laminated on the support substrate 92. A cavity 9 is thus provided. An IDT electrode 94 is provided on the piezoelectric layer 93 above the cavity 9. On both sides of the IDT electrode 94 in the acoustic wave propagation direction, reflectors 95 and 96 are provided. In FIG. 30, an outer periphery of the cavity 9 is indicated by a dashed line. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, a Lamb wave as a plate wave is excited by applying an AC electric field to the IDT electrode 94 above the cavity 9. Since the reflectors 95 and 96 are provided on both sides, resonance characteristics due to the Lamb wave can be obtained.

As described above, an acoustic wave device according to an example embodiment of the present invention may use a plate wave. In the example illustrated in FIG. 30, the IDT electrode 94, the reflector 95, and the reflector 96 are provided on the main surface corresponding to the first main surface 14a of the piezoelectric layer 14 illustrated in FIG. 1 and the like. In the acoustic wave device according to the present example embodiment, on the other hand, a pair of comb-shaped electrodes and a plurality of third electrode fingers are provided on the first main surface 14a. When the acoustic wave device according to the present example embodiment uses a plate wave, a pair of comb-shaped electrodes and a plurality of third electrode fingers as well as the reflector 95 and the reflector 96 may be provided on the first main surface 14a of the piezoelectric layer 14 in the first to fourth example embodiments and the respective modifications. In this case, the pair of comb-shaped electrodes and the plurality of third electrode fingers may be sandwiched between the reflector 95 and the reflector 96 in the electrode finger orthogonal direction.

In the acoustic wave devices of the first to fourth example embodiments and modifications, for example, the acoustic multilayer film 82 illustrated in FIG. 29 may be provided as an acoustic reflection film between the support and the piezoelectric layer. Specifically, the support and the piezoelectric layer may be arranged such that at least a portion of the support and at least a portion of the piezoelectric layer face each other across the acoustic multilayer film 82. In this case, it is sufficient that low acoustic impedance layers and high acoustic impedance layers are alternately laminated in the acoustic multilayer film 82. The acoustic multilayer film 82 may be an acoustic reflection portion in the acoustic wave device.

In the acoustic wave devices according to the first to fourth example embodiments and modifications that excite the thickness-shear mode bulk wave, as described above, d/p is, for example, preferably less than or equal to about 0.5, and more preferably less than or equal to about 0.24. This makes it possible to obtain even better resonance characteristics.

Furthermore, in the excitation region of the acoustic wave devices according to the first to fourth example embodiments and modifications that use the thickness-shear mode bulk wave, as described above, for example, MR≤about 1.75(d/p)+0.075 is preferably satisfied. More specifically, for example, MR≤about 1.75(d/p)+0.075 is preferably satisfied, where MR is the metallization ratio of the first and third electrode fingers and the second and third electrode fingers to the excitation region. In this case, spurious response can be more reliably reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer made of lithium niobate;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer to be aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period; and
a center-to-center distance between adjacent first and second electrode fingers is constant in the first comb-shaped electrode and the second comb-shaped electrode, the plurality of third electrode fingers are arranged equally or substantially equal spaced apart in the reference potential electrode, and a center-to-center distance between adjacent first and third electrode finger and a center-to-center distance between adjacent second and third electrode fingers are not constant.

2. The acoustic wave device according to claim 1, wherein the acoustic wave device is structured to excite a plate wave.

3. The acoustic wave device according to claim 1, wherein the acoustic wave device is structured to excite a thickness-shear mode bulk wave.

4. The acoustic wave device according to claim 1, further comprising:
a support laminated on the piezoelectric layer; wherein
an acoustic reflection portion is provided at a position on the support overlapping with the plurality of first electrode fingers, the plurality of second electrode fingers, and the plurality of third electrode fingers in plan view along a lamination direction of the support and the piezoelectric layer; and
d/p is less than or equal to about 0.5, where p is a longest distance of a center-to-center distance between the adjacent first and third electrode fingers and a center-to-center distance between the adjacent second and third electrode fingers, and d is a thickness of the piezoelectric layer.

5. The acoustic wave device according to claim 4, wherein
d/p is less than or equal to about 0.24.

6. The acoustic wave device according to claim 4, wherein
the acoustic reflection portion includes a cavity; and
the support and the piezoelectric layer are arranged such that a portion of the support and a portion of the piezoelectric layer face each other across the cavity.

7. The acoustic wave device according to claim 4, wherein
the acoustic reflection portion includes an acoustic reflection film including a high acoustic impedance layer with a relatively high acoustic impedance and a low acoustic impedance layer with a relatively low acoustic impedance; and
the support and the piezoelectric layer are arranged such that at least a portion of the support and at least a portion of the piezoelectric layer face each other across the acoustic reflection film.

8. The acoustic wave device according to claim 4, wherein
an excitation region is a region where the adjacent first and third electrode fingers overlap each other in an electrode finger orthogonal direction orthogonal or substantially orthogonal to a direction in which the first electrode fingers, the second electrode fingers, and the third electrode fingers extend, a region between centers of the adjacent first and third electrode fingers, and a region where the adjacent second and third electrode fingers overlap each other in the electrode finger orthogonal direction and a region between centers of the adjacent second and third electrode fingers; and
MR≤about 1.75(d/p)+0.075 is satisfied, where MR is a metallization ratio of the first electrode finger and the third electrode finger, as well as the second electrode finger and the third electrode finger to the excitation region.

9. The acoustic wave device according to claim 1, wherein
Euler angles (φ, θ, ψ) of the lithium niobate of the piezoelectric layer are within a range of Expression (1), Expression (2), or Expression (3):
(within a range of 0°±10°, 0° to 25°, any ψ) Expression (1);
(within a range of 0°±10°, 25° to 100°, 0° to 75°[(1−(θ−50)²/2500)]^{1/2} or 180°−75°[(1−(θ−50)²/2500)]^{1/2} to 180°) Expression (2); and
(within a range of 0°±10°, 180°−40°[(1−(ψ−90)²/8100)]^{1/2} to 180°, any ψ) Expression (3).

10. An acoustic wave device comprising:
a piezoelectric layer made of lithium niobate;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential;
a reference potential electrode connected to a reference potential and including a plurality of third electrode fingers on the piezoelectric layer to be aligned with the first electrode fingers and the second electrode fingers in a direction in which the first electrode fingers and the second electrode fingers are arranged, and a connection electrode connecting adjacent third electrode fingers; and
at least one fourth electrode finger on the piezoelectric layer and adjacent to a first electrode finger, a second electrode finger or a third electrode finger; wherein
in a region where the at least one fourth electrode finger is not provided, an order in which the first electrode finger, the second electrode finger, and the third electrode finger are arranged is such that, starting from the first electrode finger, the first electrode finger, the third electrode finger, the second electrode finger, and the third electrode finger define one period; and
the at least one fourth electrode finger is not connected to the input potential, the output potential, or the reference potential.

11. The acoustic wave device according to claim 10, wherein the at least one fourth electrode finger is located between one of the first electrode fingers and one of the second electrode fingers.

12. The acoustic wave device according to claim 10, wherein the at least one fourth electrode finger is adjacent to one of the third electrode fingers.

13. The acoustic wave device according to claim 10, wherein the acoustic wave device is structured to excite a plate wave.

14. The acoustic wave device according to claim 10, wherein the acoustic wave device is structured to excite a thickness-shear mode bulk wave.

15. The acoustic wave device according to claim 10, further comprising:
a support laminated on the piezoelectric layer; wherein
an acoustic reflection portion is provided at a position on the support overlapping with the plurality of first electrode fingers, the plurality of second electrode fingers, and the plurality of third electrode fingers in plan view along a lamination direction of the support and the piezoelectric layer; and
d/p is less than or equal to about 0.5, where p is a longest distance of a center-to-center distance between adjacent first and third electrode fingers and a center-to-center distance between adjacent second and third electrode fingers, and d is a thickness of the piezoelectric layer.

16. The acoustic wave device according to claim 15, wherein
d/p is less than or equal to about 0.24.

17. The acoustic wave device according to claim 15, wherein
the acoustic reflection portion includes a cavity; and
the support and the piezoelectric layer are arranged such that a portion of the support and a portion of the piezoelectric layer face each other across the cavity.

18. The acoustic wave device according to claim 10, wherein
the acoustic reflection portion includes an acoustic reflection film including a high acoustic impedance layer with a relatively high acoustic impedance and a low acoustic impedance layer with a relatively low acoustic impedance; and
the support and the piezoelectric layer are arranged such that at least a portion of the support and at least a portion of the piezoelectric layer face each other across the acoustic reflection film.

19. An acoustic wave device comprising:
a piezoelectric layer made of lithium niobate;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer so as to be aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period; and
w1≠w2, where w1 is a width of the first electrode fingers and w2 is a width of the second electrode fingers.

20. An acoustic wave device comprising:
a piezoelectric layer made of lithium niobate;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer so as to be aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period; and
a center-to-center distance between adjacent first electrode fingers and a center-to-center distance between adjacent second electrode fingers are constant in the first comb-shaped electrode and the second comb-shaped electrode, a center-to-center distance between adjacent third electrode fingers is not constant in the reference potential electrode, and a center-to-center distance between adjacent first and second electrode fingers is different from a center-to-center distance between adjacent second and third electrode fingers.
